(19) United States
(12) Patent Application Publication
(10) Pub. No.: US 2020/0273824 A1
(43) Pub. Date: Aug. 27, 2020

(54) TRANSCEIVER DIE INTERCONNECT INTERFACES

(71) Applicant: Intel Corporation, Santa Clara, CA (US)

(72) Inventors: Telesphor Kamgaing, Chandler, AZ (US); Georgios Dogiamis, Chandler, AZ (US); Hyung-Jin Lee, Portland, OR (US); Henning Braunisch, Phoenix, AZ (US); Richard Dischler, Bolton, MA (US)

(73) Assignee: Intel Corporation, Santa Clara, CA (US)

(21) Appl. No.: 16/369,836

(22) Filed: Mar. 29, 2019

(30) Foreign Application Priority Data
Feb. 22, 2019 (GR) 20190100097

(51) Int. Cl. H01L 23/66; H01L 23/00; H01L 21/48

(52) U.S. Cl. CPC H01L 23/66; H01L 24/16; H01L 21/4853; H01L 2224/81894; H01L 2223/6627; H01L 2224/16225; H01L 24/81

(57) ABSTRACT

Embodiments may relate to a microelectronic package that includes a package substrate and a signal interconnect coupled with the face of the package substrate. The microelectronic package may further include a ground interconnect coupled with the face of the package substrate. The ground interconnect may at least partially surround the signal interconnect. Other embodiments may be described or claimed.

### BACKGROUND

The next generation of computing may continue to drive increasing demand on the amount of data that needs to be moved within the datacenter rack. This demand may be further accelerated with the advent of applications requiring deep learning (DL) and artificial intelligence (AI).

### BRIEF DESCRIPTION OF THE DRAWINGS

FIG. 1 illustrates an example system that may include a transceiver die with an interconnect interface, in accordance with various embodiments.

FIG. 2 illustrates an example of an interconnect interface in a transceiver die, in accordance with various embodiments.

FIG. 3 illustrates an example simplified cross-sectional view of a microelectronic package with a transceiver die, in accordance with various embodiments.

FIG. 4 illustrates an alternative example simplified cross-sectional view of a microelectronic package with a transceiver die, in accordance with various embodiments.

FIG. 5 illustrates an alternative example simplified cross-sectional view of a microelectronic package with a transceiver die, in accordance with various embodiments.

FIG. 6 illustrates an alternative example simplified cross-sectional view of a microelectronic package with a transceiver die, in accordance with various embodiments.

FIG. 7 illustrates an alternative example simplified cross-sectional view of a microelectronic package with a transceiver die, in accordance with various embodiments.

FIG. 8 illustrates an example technique for manufacturing a microelectronic package with a transceiver die interconnect interface, in accordance with various embodiments.

FIG. 9 illustrates an example device that may use various embodiments herein, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As previously noted, there may be increased demand on the amount of data that needs to be moved within an electronic device such as a datacenter rack, between neighboring datacenter racks, or between motherboards with multiple processing sockets. In order to address the challenge of moving large amounts of data, waveguides may be used as part of the interconnect fabric. Specifically, waveguides may be used with high-speed transceiver chips. As used herein, “high-speed” may refer to electromagnetic signals with a frequency above approximately 20 gigahertz (GHz). Such signals may be signals with a frequency between approximately 20 GHz and approximately 300 GHz, which may also be referred to as “mmWave” signals. Alternatively, such “high-speed” signals may have a higher or lower frequency. For example, a “high-speed” signal may refer to a signal with a frequency as low as a few gigahertz, or a signal with a frequency above 300 GHz. A signal with a frequency higher than approximately 300 GHz may in some embodiments be referred to as a signal in the terahertz (THz)-frequency range.

The transceiver chips may be responsible for modulating/demodulating or up-converting/down-converting digital data, and may constitute an integral part of future interconnects. However, at these high speeds, and particularly at the THz-frequency range, the electromagnetic signal may suffer significant degradation in a legacy microelectronic package when it transitions from the transceiver die, through the microelectronic package of which the transceiver die is a part, and into the waveguide channel.

The signal degradation may be associated with impedance discontinuities at the first level interconnect (FLI) interface, i.e., the interface between the die and the package substrate of the microelectronic package. Specifically, in legacy microelectronic packages, the transceiver die may be coupled with the package substrate in a “flip-chip” configuration where discrete controlled-collapse chip connection (C4) bumps are used at the FLI. In addition, the cross-talk may limit the bandwidth density as multiple rows of bumps may need to be used for shielding of the signal bumps. This phenomenon may be amplified when multiple transceiver chains are co-integrated on the same die.

In contrast to the above legacy microelectronic packages that generally only include discrete C4 bumps at the FLI, embodiments herein relate to an FLI interface that includes both discrete bumps and closed-loop ground bumps. Embodiments may provide both impedance continuity, as well as produce little to no cross-talk when the signal transitions from the transceiver die into the package substrate. This may result in improved signal integrity, improved bandwidth density, better electrical performance, and form factor reduction as compared to legacy microelectronic packages. Additionally, the die-to-package substrate interface may be designed to meet design-related impedance specifications.

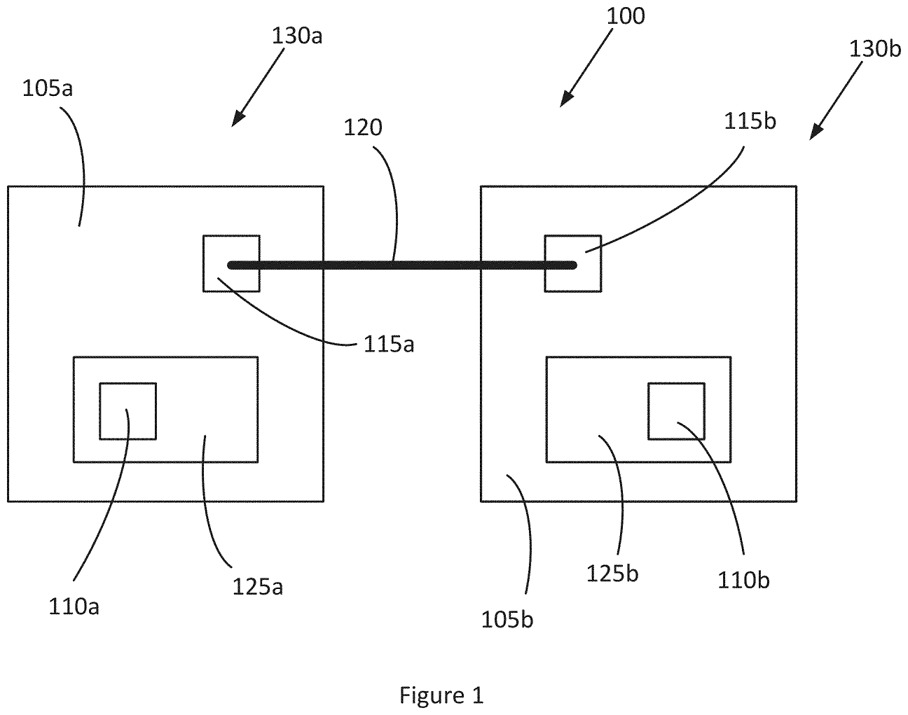

FIG. 1 illustrates an example system 100 that may include a transceiver die with an interconnect interface, in accordance with various embodiments. Specifically, the system 100 may include two microelectronic packages 130a and 130b (collectively referred to as packages 130). Respective ones of the packages 130 may include a transceiver die 125a and 125b (collectively referred to as transceiver die 125) coupled with a package substrate 105a and 105b (collectively referred to as package substrate 105).

The package substrate 105 may be formed of one or more layers of an organic or inorganic dielectric substrate material such as build-up film (BUF), low temperature co-fired ceramic, glass, etc. In embodiments, the package substrate 105 may be referred to as a cored or coreless substrate. The package substrate 105 may additionally include one or more conductive elements such as traces, pads, vias, etc. In some embodiments, the package substrate 105 may include one or more additional logic dies (e.g., a processor, a processor core, etc.) or some other type of die (e.g., a memory, etc.) either internally, externally, or at least partially imbedded within the package substrate 105.

The dies 125 may be transceiver dies. That is, the dies 125 may be configured to generate one or more electromagnetic signals for transmission as one or more high-speed/high-frequency (e.g., mmWave or THz-frequency) signals over a waveguide 120. The electromagnetic signals may themselves be referred to as a “high-frequency” electromagnetic signal and may itself have a frequency on the order of a mmWave frequency or a THz-frequency. For example, the dies 125 may include, or be coupled with, various logic or circuit elements such as a processor, a central processing unit (CPU), a general processing unit (GPU), a core of a processor, a modulator/demodulator, a quadrature mixer, an amplifier, an oscillator, a filter, an equalizer, an analog-to-digital converters (ADC), a digital-to-analog converter (DAC), and digital signal processing (DSP) logic blocks etc. which may be configured to process data and generate the one or more electromagnetic signals based on the processing signals. Additionally, in some embodiments the dies 125 may include memory, or be coupled with some other components which may be configured to store or otherwise process the data. In some embodiment one or both of the dies 125 may be considered to be, or be related to or coupled with, radio frequency (RF) circuitry designed to transmit, receive, facilitate transmission of, facilitate reception of, or otherwise process, generate, or alter one or more RF signals from a radiative antenna. Such signals may be, for example, signals in accordance with second generation (2G) transmission protocols, third generation (3G) transmission protocols, fourth generation (4G) transmission protocols, fifth generation (5G) transmission protocols, Bluetooth® transmission protocols, Wi-Fi transmission protocols, or some other wireless transmission protocol either known or subsequently developed.

Conversely, the dies 125 may additionally or alternatively be configured to receive and process one or more signals received over the waveguide 120. For example, the signal may be received over the waveguide 120 and then transmitted to a logic element, an additional component such as a memory, etc. for processing.

In some embodiments, a transceiver die 125 may serve both transmission and reception functions. For example, in some embodiments the die 125 may be configured to process an electromagnetic signal related to a high-speed/high-frequency signal received over a first waveguide, and facilitate the re-transmission of that signal over a second waveguide with minimal or no processing.

It will be understood that even though in the above descriptions the dies are discussed as communicatively coupled with the waveguide 120, generally the signal path may include transmission of the signal from a die 125, through the package substrate 105, and into the waveguide 120 (or vice-versa).

Each of the dies 125 may include RF circuitry 110a and 110b (collectively, RF circuitry 110). If the RF circuitry 110 is in the transmit path (i.e., die->package substrate->waveguide), the RF circuitry 110 may be configured to process or otherwise alter one or more signals received from the logic component of the die 125 prior to transmission of the signal into the package substrate 105. Such processing or alteration may include, for example, modulation of the signal, up-conversion, amplification of the signal, etc. Additionally or alternatively, if the RF circuitry 110 is in the receive path (i.e., waveguide->package substrate->die), the RF circuitry 110 may be configured to process or otherwise alter one or more signals received from the package substrate 105 prior to transmission of the signal into the die 125. Such processing or alteration may include, for example, amplification, phase shifting, de-modulation of the signal, down-conversion of the signal, filtering, equalization, and digitization of the signal, etc.

The waveguide 120 may be one (or more) of a variety of waveguides. For example, the waveguide 120 may be a coaxial waveguide, a dielectric waveguide, a standalone cable, a channel built into a package, a channel built into a printed circuit board (PCB) substrate, or some other type of waveguide. In some embodiments, the waveguide 120 may have a length on the order of less than 5 meters (m), though in other embodiments the waveguide 120 may have a greater length. In some embodiments, the waveguide 120 may have a length measured on the order of centimeters (cm), tens of cm, hundreds of cm, or less. The length of the waveguide may be based on factors such as signal strength, system design parameters, etc. In some embodiments, the waveguide 120 may include one or more additional components such as repeaters, etc.

The package substrates 105 may further include one or more signal launchers 115a and 115b (collectively referred to herein as signal launchers 115). In embodiments, the signal launchers 115 may also be referred to as a “wave launcher.” The signal launchers 115 may be configured to physically convert the mode of the electromagnetic signal (or high-frequency electromagnetic wave) in the package substrate 105 into another mode that matches the propagation characteristics of the waveguide channel 120 as described above and then launch the electromagnetic wave into waveguide 120. Conversely, the signal launchers 115 may additionally or alternatively be configured to convert an electromagnetic wave received from waveguide 120 into an electromagnetic signal which may then be communicated by the package substrate 105 to a die 125 and, more particularly, to the RF circuitry 110 of the die 125. In embodiments, the signal launcher 115 may include an element such as parallel metal plates, via-fed stacked metal patches microstrip-to-tapered slot-line transitions, an antenna, or some other element that may convert the mode of an electromagnetic signal.

As an example of the system 100 in operation, the system 100 may be configured to transmit the signal from one package 130a, through waveguide 120, to package 130b. Specifically, the transceiver die 125a of package 130a may generate an electromagnetic signal. The RF circuitry 110a of transceiver die 125a may alter the signal through modulation, up-conversion, or some other alteration. The altered signal may then be provided to package substrate 105a and, through package substrate 105a (and more particularly one or more vias, traces, pads, etc. of package substrate 105a), to signal launcher 115a where it may be converted as described above and launched into waveguide 120. The electromagnetic signal may propagate through the waveguide 120 to package 130b where it may be provided to signal launcher 115b and converted from an electromagnetic signal with a mode appropriate to propagation through the waveguide 120 into an electromagnetic signal with a mode appropriate to propagation through the package 130b. The signal may then propagate through package substrate 105b (and more particularly one or more of the various vias, traces, pads, etc. of the package substrate 105b) to die 125b and, specifically, the RF circuitry 110b of die 125b. The RF circuitry 110b may alter the signal through one or more techniques such as de-modulation, down-conversion, etc., and provide the altered signal to one or more processors or other components of the die 125b. In this example, the package 130a may be, for example, a processor or some other type of computing component of a datacenter, and the package 130b may be, for example, a network switch or some other type of computing component of a datacenter.

It will be understood that the above description of the system 100 is intended as only one example of embodiments herein. For example, in other embodiments the different packages 130 may be different elements of a datacenter. The relative numbers, sizes, or shapes of the various elements depicted in FIG. 1 may vary in other embodiments. Certain elements such as package substrates 105a and 105b may be the same as one another, or they may be different types of package substrates. Similarly, dies 125a and 125b may be the same as one another in one embodiment, while they may be different types of transceiver dies in different embodiments. In some embodiments, certain elements such as the RF circuitry 110 may not be present on one or both of dies 125, but rather may be positioned on or in the package substrates 105. Other variations may be present in other embodiments.

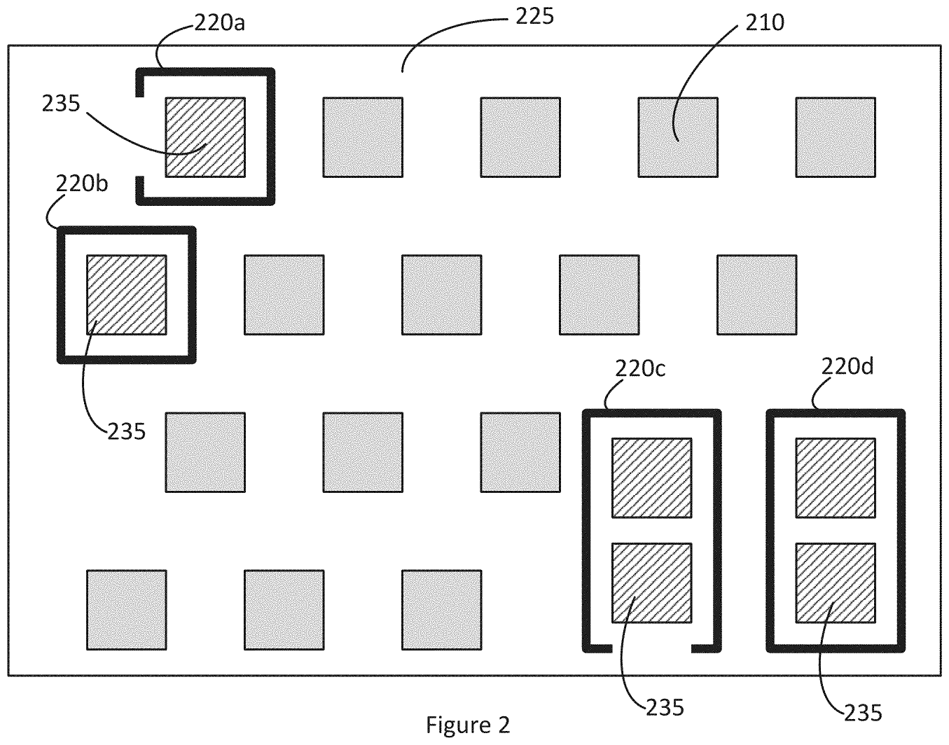

By contrast, FIG. 2 illustrates an example of interconnect interfaces in a transceiver die, in accordance with various embodiments. Specifically, FIG. 2 depicts a transceiver die 225, which may be similar to dies 125. The die 225 may include a plurality of bumps, which may be bumps of an FLI as described above. For example, the bumps may be C4 bumps of the FLI as described above. It will be understood that each and every element of FIG. 2 may not be specifically enumerated, however elements that share similar characteristics (e.g., shading) may be consider to be similar to one another unless explicitly stated otherwise.

Generally, the die 225 may include a plurality of bumps 210 which may be configured to carry one or more power signals between the die 225 and a package substrate to which the die 225 is coupled. In some embodiments, one or more of the bumps 210 may be configured to carry a low-frequency electromagnetic signal (e.g., an electromagnetic signal with a frequency below approximately 20 GHz) between the die 225 and the package substrate to which the die 225 is coupled. Additionally or alternatively, one or more of the bumps 210 may be a “ground” bump that may be electrically coupled with ground.

The die 225 may additionally include one or more high-frequency signal bumps 235. The high-frequency signal bumps 235 may be configured to convey one or more high-frequency electromagnetic signals (e.g., electromagnetic signals in the mmWave frequency, THz-frequency, or above range) between the die 225 and a package substrate to which the die is coupled.

The die 225 may also include one or more ground bumps 220a, 220b, 220c, and 220d (collectively referred to herein as ground bumps 220). Generally, the ground bumps 220 may be configured to be coupled to a ground of the microelectronic package of which the die 225 is a part. In some embodiments, the ground bumps 220 may be configured to couple to a power supply and carry power between the die 225 and a package substrate to which the die 225 is coupled. However, for ease of reference herein, the bumps 220 will generally be referred to as “ground bumps.”

As can be seen in FIG. 2, the ground bumps 220 may generally surround the high-frequency signal bumps 235 on one or more sides of the high-frequency signal bumps 235. Specifically, the ground bumps 220 may isolate and at least partially electromagnetically shield the high-frequency signal bumps 235 from the bumps 210. In this way, the ground bumps 220 may help in providing impedance continuity and cross-talk mitigation at the FLI for the high-frequency signal bumps 235.

It will be observed that the ground bumps 220 may have different configurations as shown in FIG. 2. For example, ground bump 220a may not entirely surround a high-frequency signal bump 235, but rather may be open on one or more sides of the high-frequency signal bump 235. The ground bump 220a may not fully enclose the high-frequency signal bump 235 because there may not be a cross-talk producing component (e.g., a bump 210) on all sides of the high-frequency signal bump 235. Therefore, it may be desirable to leave the ground bump 220a “open” to reduce manufacturing cost and material usage. By contrast, ground bump 220b may fully surround a high-frequency signal bump 235. In some embodiments, the ground bump 220a may not fully encircle the high-frequency signal bump 235 because such a design may allow modulation of the impedance of the transition from die to package or enablement of trace routing on the die or package top-metal layer.

In some embodiments, a single ground bump 220 may surround two or more high-frequency signal bumps 235. For example, ground bumps 220c and 220d may each surround two high-frequency signal bumps 235. The high-frequency signal bumps 235 surrounded by ground bumps 220c (or ground bumps 220d) may be bumps of a differential pair of high-frequency signal bumps.

It will be understood that the above-described configuration, including the placement of certain elements, is intended only as one example configuration and other embodiments may have different configurations including different sizes, shapes, numbers, or placement of the various depicted elements. For example, although the various bumps are depicted as having a generally square shape in FIG. 2, in other embodiments the bumps may have a different shape such as circular, oblong, hexagonal, triangular, rectangular, or some other shape.

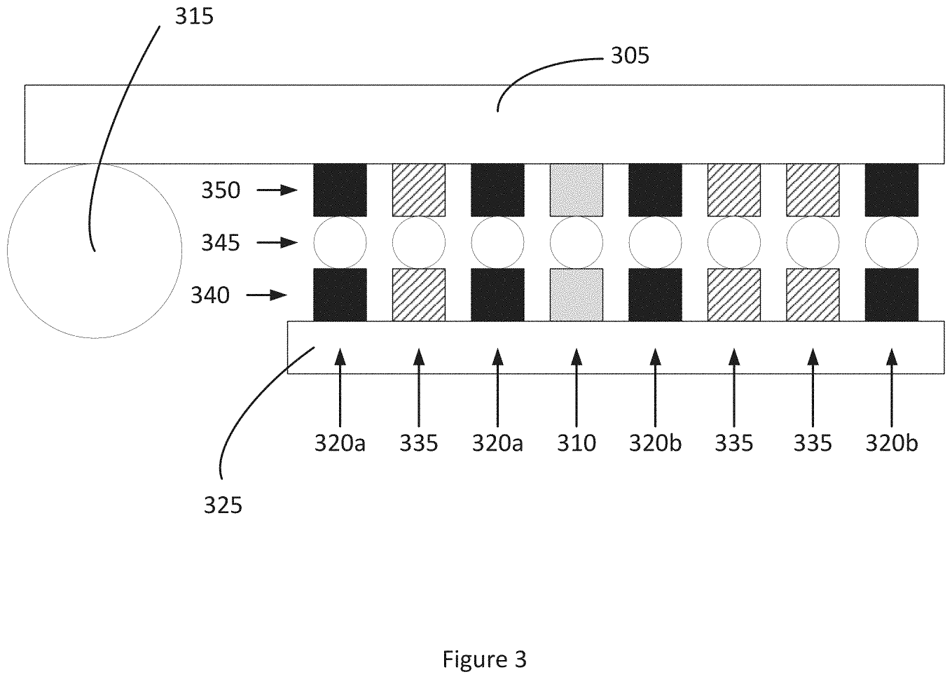

FIGS. 3-7 depict various example configurations by which a transceiver die may be coupled with a package substrate in accordance with various embodiments herein. It will be understood that, unless explicitly stated otherwise, the specific configurations or dimensions depicted are for the sake of explanation of concepts of the embodiments, and specific dimensions, either relative or actual, are not intended. Additionally, the number or placement of various elements may different in other embodiments, and so a specific number of interconnects, bumps, etc. should not be inferred from the Figures unless explicitly stated otherwise. In some embodiments, additional materials (e.g., an underfill between the die and the package substrate) may be present which may not be explicitly illustrated in the various Figures. Finally, it will be understood that elements that include similar shading between FIGS. 3-7, or elements that share shading between FIGS. 3-7 and FIG. 2, may share similar characteristics as one another. Each and every element may not be specifically enumerated or discussed in each Figure for the sake of brevity and lack of redundancy.

FIG. 3 illustrates an example simplified cross-sectional view of a microelectronic package with a transceiver die, in accordance with various embodiments. Specifically, the package may include a package substrate 305 which may be similar to, and share characteristics with, package substrate 105. A transceiver die 325, which may be similar to, and share characteristics with, transceiver die 125, may be coupled with the package substrate 305. The package substrate 305 may include one or more second-level interconnects 315, which may be used to couple the package substrate to a PCB of an electronic device such as a mother board, an interposer, or some other type of interposer. The second-level interconnect 315 may be, for example, a ball of a ball grid array (BGA), a pin of a pin grid array (PGA), an element of a land grid array (LGA), a conductive pillar, or some other structure such as a socket.

The die 325 may be coupled with the package substrate 305 by a plurality of bumps 310, ground bumps 320a/320b, and high-frequency signal bumps 335 in an FLI, which may be respectively similar to, and share one or more characteristics with, bumps 210, ground bumps 220, and high-frequency signal bumps 235. Similarly to the ground bumps 220 of FIG. 2, the ground bumps 320a/320b may surround one or more high-frequency signal bumps 335. For example, the ground bump 320a may only surround a single high-frequency signal bump 335, while the ground bump 320b may surround a plurality of high-frequency signal bumps 335.

As depicted in FIG. 3, the FLI may include three layers. There may be a package-side layer 350 of the FLI, a die-side layer 340 of the FLI, and a coupling layer 345 of the FLI. Generally, the coupling layer 345 may include a plurality of coupling elements, represented as the circular elements in the coupling layer 345 of FIG. 3. The coupling elements may be, for example, solder balls or some other type of coupling that may be able to physically and communicatively couple the die-side layer 340 of the FLI with the package-side layer 350 of the FLI.

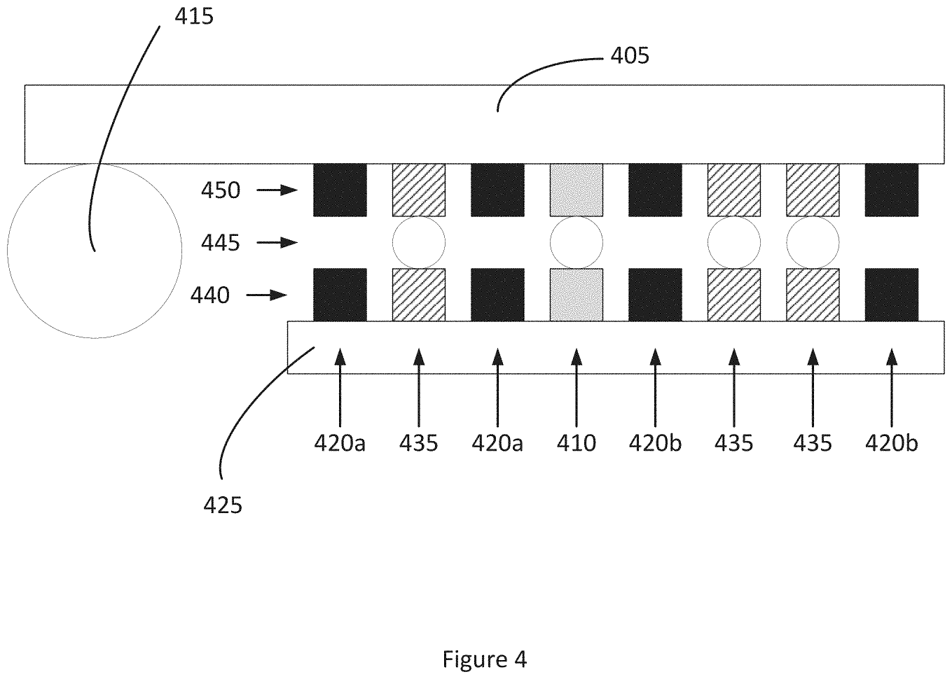

FIG. 4 illustrates an alternative example simplified cross-sectional view of a microelectronic package with a transceiver die, in accordance with various embodiments. Specifically, the package may include a package substrate 405 coupled with a transceiver die 425, which may be similar to, and share characteristics with, package substrate 305 and transceiver die 325. The package substrate 405 may include one or more second-level interconnects 415, which may be similar to, and share characteristics with, second-level interconnect 315.

The die 425 may be coupled with the package substrate 405 by one or more high-frequency signal bumps 435 and one or more power bumps 410, which may be respectively similar to, and share one or more characteristics with, high-frequency signal bumps 335 and bumps 310. The various bumps may be elements of an FLI that includes a die-side layer 440 and a package-side layer 450, which may be respectively similar to, and share characteristics of, die-side layer 340 and package-side layer 350.

The package may further include one or more ground bumps 420a and 420b, and a coupling layer 445 of the FLI, which may be respectively similar to, and share characteristics of, ground bumps 320a and 320b, and coupling layer 345. However, as can be seen in FIG. 4, in some embodiments the ground bumps 320a and 320b may not have a coupling element at the coupling layer. This lack of a coupling element may be because the bumps in the die-side layer 440 and the package-side layer 450 may sufficiently shield the high-frequency signal bumps 435, and so the coupling element may be unnecessary and therefore eliminated to reduce manufacturing cost or complexity.

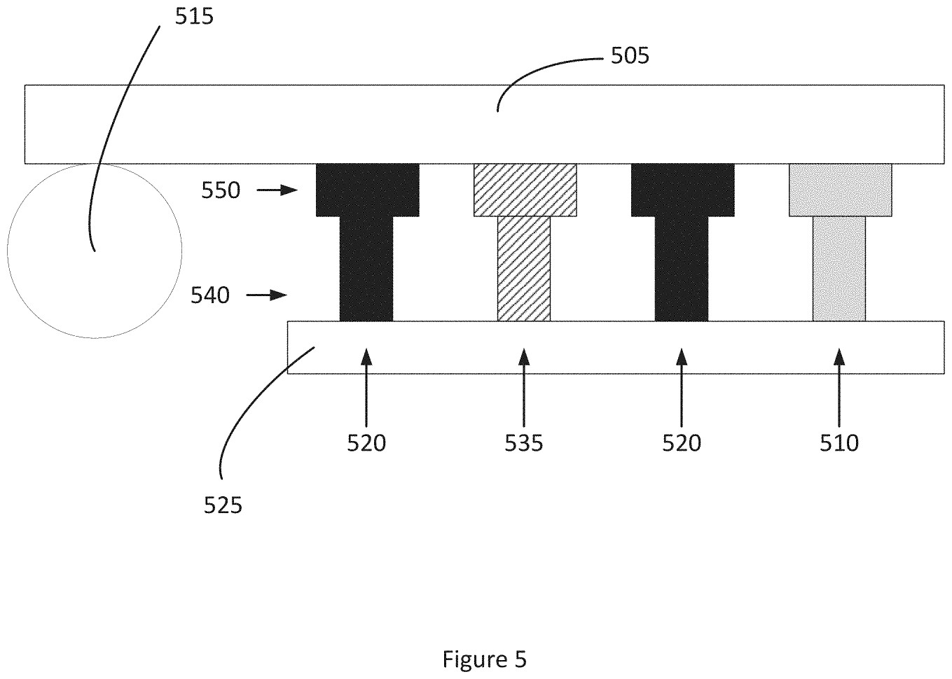

FIG. 5 illustrates an alternative example simplified cross-sectional view of a microelectronic package with a transceiver die, in accordance with various embodiments. Specifically, the package may include a package substrate 505 coupled with a transceiver die 525, which may be similar to, and share characteristics with, package substrate 305 and transceiver die 325. The package substrate 505 may include one or more second-level interconnects 515, which may be similar to, and share characteristics with, second-level interconnect 315.

The package may further include an FLI with a die-side layer 540 and a package-side layer 550, which may be respectively similar to, and share one or more characteristics with, die-side layer 340 and package-side layer 350. One or more bumps such as high-frequency signal bumps 535, ground bumps 520, and power bumps 510 may be positioned with the FLI, and may be similar to, and share one or more characteristics with, high-frequency signal bumps 335, ground bumps 320a, and bumps 310. It will be understood that ground bumps such as ground bump 320b may also be present in FIG. 5, however the number of bumps depicted is reduced for the sake of clearer depiction of the various elements.

As can be seen in FIG. 5, the FLI may not include a coupling layer such as coupling layer 345. Rather, the bumps of the die-side layer 540 may be directly coupled with the bumps of the package-side layer 550 through, for example, metal-to-metal bonding. As depicted in FIG. 5, the bumps of the die-side layer 540 may be considered to be pillars, while the bumps of the package-side layer 550 may be considered to be pads of the package substrate 505. However, in other embodiments the bumps of the die-side layer 540 may be pads and the bumps of the package-side layer 550 may be pillars, the bumps of both layers may be pillars or pads, or the bumps may be some other type of interconnect element such as a solder bump which may be coupled through metal-to-metal bonding.

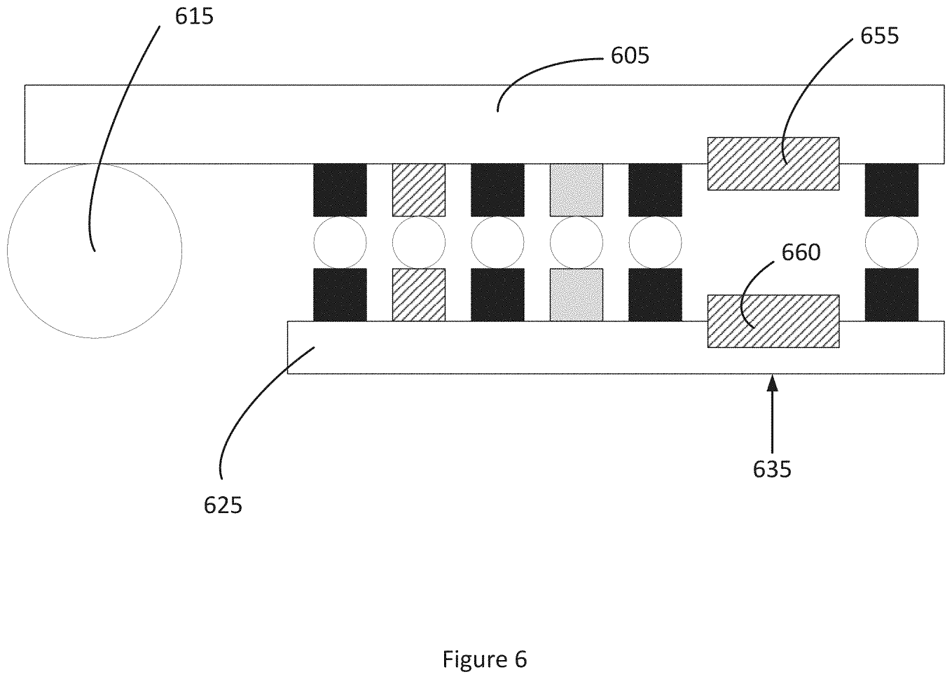

FIG. 6 illustrates an alternative example simplified cross-sectional view of a microelectronic package with a transceiver die, in accordance with various embodiments. The package may include a transceiver die 625, a package substrate 605, and a second-level interconnect 615 which may be respectively similar to, and share one or more characteristics of, the transceiver die 325, package substrate 305, and second-level interconnect 315. Although not specifically enumerated for the sake of brevity and elimination of redundancy, the package may further include one or more ground bumps, power bumps, and high-frequency signal bumps in an FLI that may include a die-side layer, a package-side layer, and a coupling layer as previously described and depicted in FIGS. 3-5.

In some embodiments, rather than having a high-frequency signal bump that includes two elements coupled (directly or indirectly) with one another (e.g., such as high-frequency signal bumps 435 or 535), the package may include a high-frequency signal element 635 that includes two resonant patches 660 and 655 that are physically separated from one another. Specifically, a first resonant patch 660 may be coupled with, or an element of, die 625. Additionally, a second resonant patch 655 may be coupled with, or an element of, package substrate 605. As shown, the resonant patches 655 and 660 may be at least partially embedded within the package substrate 605 and the die 625, respectively, however in other embodiments one or both of the resonant patches 655/660 may be fully embedded within, or positioned on the surface of, the package substrate 605 or the die 625. Generally, in operation, an electromagnetic wave arriving on one patch (e.g. resonant patch 660) may be coupled capacitively or electromagnetically with the other patch (e.g., resonant patch 655), and in that way the high-speed signal may be transmitted from one element (e.g., the die 625) to the other element (e.g., the package substrate 605). It will be understood that the die->package substrate transmission is merely intended as an example and, in other embodiments, the transmission may likewise occur in the opposite direction (package substrate->die).

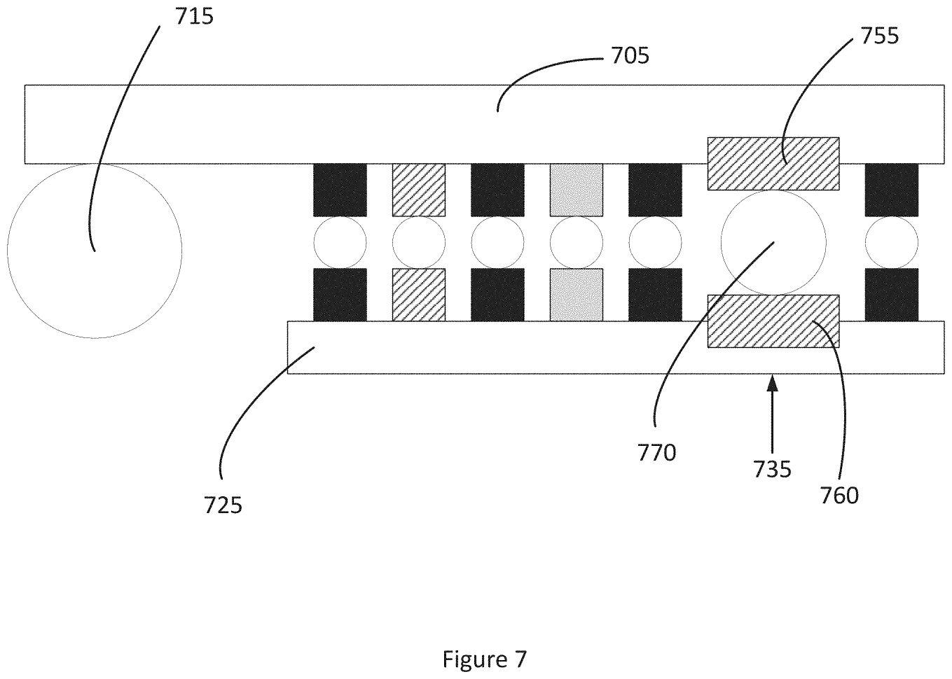

FIG. 7 illustrates an alternative example simplified cross-sectional view of a microelectronic package with a transceiver die, in accordance with various embodiments. The package may include a transceiver die 725, a package substrate 705, and a second-level interconnect 715 which may be respectively similar to, and share one or more characteristics of, the transceiver die 325, package substrate 305, and second-level interconnect 315. Although not specifically enumerated for the sake of brevity and elimination of redundancy, the package may further include one or more ground bumps, power bumps, and high-frequency signal bumps in an FLI that may include a die-side layer, a package-side layer, and a coupling layer as previously described and depicted in FIGS. 3-6.

The package may include a high-frequency signal element 735 that includes two pads 755 and 760. The pads may be coupled with a dielectric resonator 770. As seen in FIG. 7, in some embodiments the dielectric resonator 770 may have a generally circular or spherical shape, while in other embodiments the dielectric resonator 770 may have a different shape. In operation, the dielectric resonator exhibits a resonance at the desired frequency of operation and therefore enables maximum power transfer between pad 755 and pad 760.

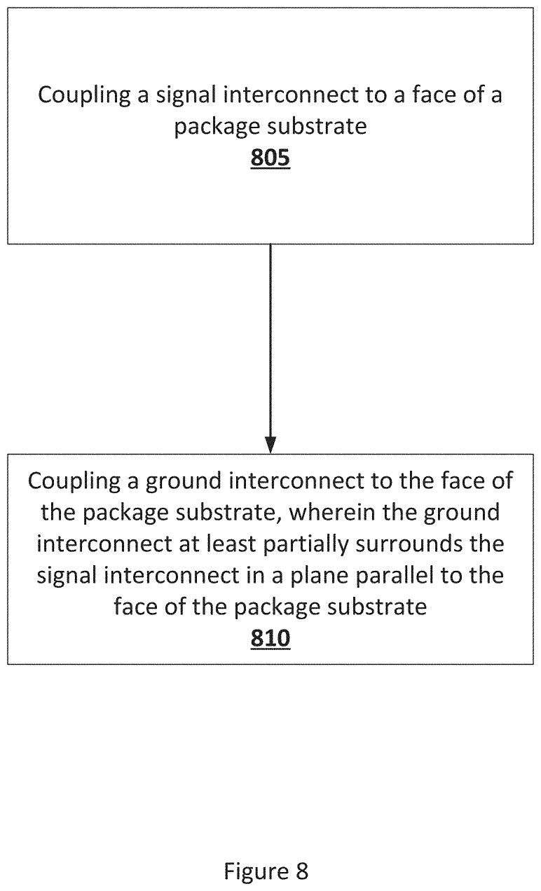

FIG. 8 illustrates an example technique for manufacturing a microelectronic package with a transceiver die interconnect interface, in accordance with various embodiments. Generally, the technique may be described with reference to elements of FIG. 3, however it will be understood that one or more elements of the technique may be applied, in whole or in part, to elements of the embodiments depicted in one of FIGS. 2, 4-6, or some other embodiment of the ideas described herein. The technique may be applied to these other embodiments, in whole or in part, with or without modification.

Generally, the technique may include coupling, at 705, a signal interconnect to a face of a package substrate. The signal interconnect may be, for example, a high-speed signal bump such as high-speed signal bumps 335. The package substrate may be similar to, for example, package substrate 305.

The technique may further include coupling, at 710, a ground interconnect to the face of the package substrate. The ground interconnect may at least partially surround the signal interconnect in a plane parallel to the face of the package substrate. The ground interconnect may be similar to, for example, ground bumps 320a or 320b.

It will be understood that this embodiment of the technique is intended as one example embodiment. Other embodiments may have more or fewer elements than this example technique, and two or more of the elements may be performed concurrently with each other, or the elements may be performed in a different order.

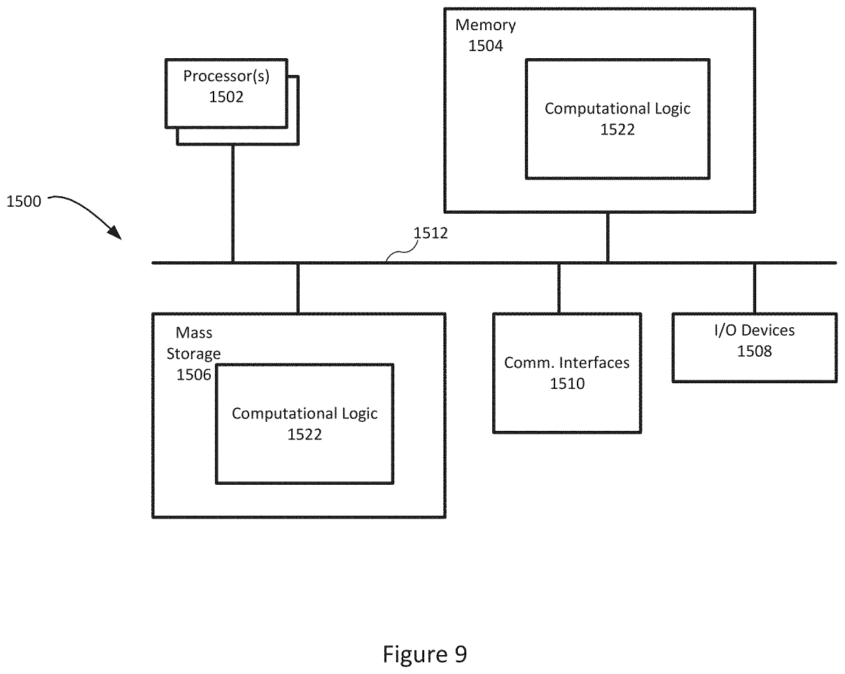

FIG. 9 illustrates an example electronic device 1500 suitable for use with system 100, one or more of the microelectronic packages of FIGS. 3-7, or some other microelectronic package, in accordance with various embodiments. Specifically, in some embodiments, the electronic device 1500 may include one or more of the system or microelectronic packages.

As shown, electronic device 1500 may include one or more processors or processor cores 1502 and system memory 1504. For the purpose of this application, including the claims, the terms “processor” and “processor cores” may be considered synonymous, unless the context clearly requires otherwise. The processor 1502 may include any type of processors, such as a CPU, a microprocessor, and the like. The processor 1502 may be implemented as an integrated circuit having multi-cores, e.g., a multi-core microprocessor. The electronic device 1500 may include mass storage devices 1506 (such as diskette, hard drive, volatile memory (e.g., DRAM, compact disc read-only memory (CD-ROM), digital versatile disk (DVD), and so forth)). In general, system memory 1504 and/or mass storage devices 1506 may be temporal and/or persistent storage of any type, including, but not limited to, volatile and non-volatile memory, optical, magnetic, and/or solid-state mass storage, and so forth. Volatile memory may include, but is not limited to, static and/or DRAM. Non-volatile memory may include, but is not limited to, electrically erasable programmable read-only memory, phase change memory, resistive memory, and so forth. In some embodiments, one or both of the system memory 1504 or the mass storage device 1506 may include computational logic 1522, which may be configured to implement or perform, in whole or in part, one or more instructions that may be stored in the system memory 1504 or the mass storage device 1506. In other embodiments, the computational logic 1522 may be configured to perform a memory-related command such as a read or write command on the system memory 1504 or the mass storage device 1506.

The electronic device 1500 may further include input/output (I/O) devices 1508 (such as a display (e.g., a touchscreen display), keyboard, cursor control, remote control, gaming controller, image capture device, and so forth) and communication interfaces 1510 (such as network interface cards, modems, infrared receivers, radio receivers (e.g., Bluetooth), and so forth).

The communication interfaces 1510 may include communication chips (not shown) that may be configured to operate the device 1500 in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 1510 may operate in accordance with other wireless protocols in other embodiments.

The electronic device 1500 may further include or be coupled with a power supply. The power supply may, for example, be a power supply that is internal to the electronic device 1500 such as a battery. In other embodiments the power supply may be external to the electronic device 1500. For example, the power supply may be an electrical source such as an electrical outlet, an external battery, or some other type of power supply. The power supply may be, for example alternating current (AC), direct current (DC) or some other type of power supply. The power supply may in some embodiments include one or more additional components such as an AC to DC convertor, one or more downconverters, one or more upconverters, transistors, resistors, capacitors, etc. that may be used, for example, to tune or alter the current or voltage of the power supply from one level to another level. In some embodiments the power supply may be configured to provide power to the electronic device 1500 or one or more discrete components of the electronic device 1500 such as the processor(s) 1502, mass storage 1506, 1/O devices 1508, etc.

The above-described electronic device 1500 elements may be coupled to each other via system bus 1512, which may represent one or more buses. In the case of multiple buses, they may be bridged by one or more bus bridges (not shown). Each of these elements may perform its conventional functions known in the art. The various elements may be implemented by assembler instructions supported by processor(s) 1502 or high-level languages that may be compiled into such instructions.

The permanent copy of the programming instructions may be placed into mass storage devices 1506 in the factory, or in the field, through, for example, a distribution medium (not shown), such as a compact disc (CD), or through communication interface 1510 (from a distribution server (not shown)). That is, one or more distribution media having an implementation of the agent program may be employed to distribute the agent and to program various electronic devices.

The number, capability, and/or capacity of the elements 1508, 1510, 1512 may vary, depending on whether electronic device 1500 is used as a stationary electronic device, such as a set-top box or desktop computer, or a mobile electronic device, such as a tablet electronic device, laptop computer, game console, or smartphone. Their constitutions are otherwise known, and accordingly will not be further described.

In various implementations, the electronic device 1500 may comprise one or more components of a data center, a laptop, a netbook, a notebook, an ultrabook, a smartphone, a tablet, a personal digital assistant (PDA), an ultra-mobile PC, a mobile phone, or a digital camera. In further implementations, the electronic device 1500 may be any other electronic device that processes data.

As noted, in some embodiments the electronic device 1500 may include one or more of system 100, one or more of the microelectronic packages of FIGS. 3-7, or some other microelectronic package. For example, in some embodiments the dies of one or more of the system or the microelectronic packages may be, include, or be coupled with a processor 1502, a memory 1504, a communication interface 1510, etc.

### Examples of Various Embodiments

Example 1 includes a microelectronic package comprising: a package substrate; a power interconnect coupled with a face of the package substrate, wherein the power interconnect is to carry a power signal to or from the package substrate; a signal interconnect coupled with the face of the package substrate, wherein the signal interconnect is to carry a data signal with a frequency of at least 20 gigahertz (GHz) to or from the package substrate; and a ground interconnect coupled with the face of the package substrate, wherein the ground interconnect is to electrically couple with a ground and wherein the ground interconnect at least partially surrounds the signal interconnect.

Example 2 includes the microelectronic package of example 1, wherein the data signal has a frequency of at least 300 GHz.

Example 3 includes the microelectronic package of example 1, further comprising a die coupled with the face of the package substrate, wherein the die is communicatively coupled with the signal interconnect.

Example 4 includes the microelectronic package of example 3, wherein the signal interconnect is to carry the data signal between the die and the package substrate.

Example 5 includes the microelectronic package of any of examples 1-4, wherein the ground interconnect is positioned between the signal interconnect and the power interconnect, and the ground interconnect is further positioned between the signal interconnect and another power interconnect coupled with the face of the package substrate.

Example 6 includes the microelectronic package of any of examples 1-4, wherein the ground interconnect entirely surrounds the signal interconnect in a plane parallel to the face of the package substrate.

Example 7 includes the microelectronic package of any of examples 1-4, wherein the signal interconnect is a first signal interconnect, and wherein the microelectronic package further comprises a second signal interconnect coupled with the face of the package substrate, and wherein the ground interconnect at least partially surrounds the second signal interconnect.

Example 8 includes a microelectronic package comprising: a package substrate that includes a face; a die coupled with the face of the package substrate; a signal interconnect coupled with the face of the package substrate and the die, wherein the signal interconnect is to carry a data signal with a frequency of greater than 30 gigahertz (GHz) between the package substrate and the die; and a ground interconnect coupled with the face of the package substrate and the die, wherein the ground interconnect is electrically coupled with a ground, and wherein the ground interconnect forms at least a partial loop around the signal interconnect in a plane parallel to the face of the package substrate.

Example 9 includes the microelectronic package of example 8, wherein: the signal interconnect includes a first signal portion coupled with the package substrate and a second signal portion coupled with the die; and the ground interconnect includes a first ground portion coupled with the package substrate and a second ground portion coupled with the die.

Example 10 includes the microelectronic package of example 9, wherein the first signal portion is coupled with the second signal portion by solder.

Example 11 includes the microelectronic package of example 9, wherein the first ground portion is not coupled with the second ground portion.

Example 12 includes the microelectronic package of example 9, wherein the first signal portion is coupled to the second signal portion by a metal-to-metal bond.

Example 13 includes the microelectronic package of example 9, wherein the first signal portion is a first resonant patch and the second signal portion is a second resonant patch.

Example 14 includes the microelectronic package of example 13, further comprising a dielectric resonator positioned between, and coupled with, the first patch and the second patch.

Example 15 includes the microelectronic package of any of examples 8-14, wherein the microelectronic package further includes one or more interconnects coupled with the face, wherein the one or more interconnects are to couple with a PCB.

Example 16 includes the microelectronic package of any of examples 8-14, further comprising a first power interconnect and a second power interconnect coupled with the face of the package substrate and the die, wherein the ground interconnect is between the signal interconnect and the first power interconnect, and the ground interconnect is further between the signal interconnect and the second power interconnect.

Example 17 includes a method of manufacturing a microelectronic package, wherein the method comprises: coupling a signal interconnect to a face of a package substrate, wherein the signal interconnect is to carry a millimeter wave (mmWave) or a terahertz-band signal between the package substrate and a die coupled with the face of the package substrate; and coupling a ground interconnect to the face of the package substrate, wherein the ground interconnect is to couple to a ground, and wherein the ground interconnect at least partially surrounds the signal interconnect in a plane parallel to the face of the package substrate.

Example 18 includes the method of example 17, further comprising coupling the die with the face of the package substrate such that the die is communicatively coupled with the signal interconnect.

Example 19 includes the method of examples 17 or 18, wherein the signal interconnect is a first signal interconnect, and further comprising coupling a second signal interconnect to the face of the package substrate, and wherein the ground interconnect at least partially surrounds the second signal interconnect.

Example 20 includes the method of examples 17 or 18, wherein the ground interconnect entirely surrounds the signal interconnect in the plane parallel to the face of the package substrate.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A microelectronic package comprising:
a package substrate;
a power interconnect coupled with a face of the package substrate, wherein the power interconnect is to carry a power signal to or from the package substrate;
a signal interconnect coupled with the face of the package substrate, wherein the signal interconnect is to carry a data signal with a frequency of at least 20 gigahertz (GHz) to or from the package substrate; and
a ground interconnect coupled with the face of the package substrate, wherein the ground interconnect is to electrically couple with a ground and wherein the ground interconnect at least partially surrounds the signal interconnect.

2. The microelectronic package of claim 1, wherein the data signal has a frequency of at least 300 GHz.

3. The microelectronic package of claim 1, further comprising a die coupled with the face of the package substrate, wherein the die is communicatively coupled with the signal interconnect.

4. The microelectronic package of claim 3, wherein the signal interconnect is to carry the data signal between the die and the package substrate.

5. The microelectronic package of claim 1, wherein the ground interconnect is positioned between the signal interconnect and the power interconnect, and the ground interconnect is further positioned between the signal interconnect and another power interconnect coupled with the face of the package substrate.

6. The microelectronic package of claim 1, wherein the ground interconnect entirely surrounds the signal interconnect in a plane parallel to the face of the package substrate.

7. The microelectronic package of claim 1, wherein the signal interconnect is a first signal interconnect, and wherein the microelectronic package further comprises a second signal interconnect coupled with the face of the package substrate, and wherein the ground interconnect at least partially surrounds the second signal interconnect.

8. A microelectronic package comprising:
a package substrate that includes a face;
a die coupled with the face of the package substrate;
a signal interconnect coupled with the face of the package substrate and the die, wherein the signal interconnect is to carry a data signal with a frequency of greater than 30 gigahertz (GHz) between the package substrate and the die; and
a ground interconnect coupled with the face of the package substrate and the die, wherein the ground interconnect is electrically coupled with a ground, and wherein the ground interconnect forms at least a partial loop around the signal interconnect in a plane parallel to the face of the package substrate.

9. The microelectronic package of claim 8, wherein:
the signal interconnect includes a first signal portion coupled with the package substrate and a second signal portion coupled with the die; and
the ground interconnect includes a first ground portion coupled with the package substrate and a second ground portion coupled with the die.

10. The microelectronic package of claim 9, wherein the first signal portion is coupled with the second signal portion by solder.

11. The microelectronic package of claim 9, wherein the first ground portion is not coupled with the second ground portion.

12. The microelectronic package of claim 9, wherein the first signal portion is coupled to the second signal portion by a metal-to-metal bond.

13. The microelectronic package of claim 9, wherein the first signal portion is a first patch and the second signal portion is a second patch.

14. The microelectronic package of claim 13, further comprising a dielectric resonator positioned between, and coupled with, the first patch and the second patch.

15. The microelectronic package of claim 8, wherein the microelectronic package further includes one or more interconnects coupled with the face, wherein the one or more interconnects are to couple with a printed circuit board (PCB).

16. The microelectronic package of claim 8, further comprising a first power interconnect and a second power interconnect coupled with the face of the package substrate and the die, wherein the ground interconnect is between the signal interconnect and the first power interconnect, and the ground interconnect is further between the signal interconnect and the second power interconnect.

17. A method of manufacturing a microelectronic package, wherein the method comprises:
coupling a signal interconnect to a face of a package substrate, wherein the signal interconnect is to carry a millimeter wave (mmWave) or a terahertz-band signal between the package substrate and a die coupled with the face of the package substrate; and
coupling a ground interconnect to the face of the package substrate, wherein the ground interconnect is to couple to a ground, and wherein the ground interconnect at least partially surrounds the signal interconnect in a plane parallel to the face of the package substrate.

18. The method of claim 17, further comprising coupling the die with the face of the package substrate such that the die is communicatively coupled with the signal interconnect.

19. The method of claim 17, wherein the signal interconnect is a first signal interconnect, and further comprising coupling a second signal interconnect to the face of the package substrate, and wherein the ground interconnect at least partially surrounds the second signal interconnect.

20. The method of claim 17, wherein the ground interconnect entirely surrounds the signal interconnect in the plane parallel to the face of the package substrate.
